(19) United States
(12) Patent Application Publication
(10) Pub. No.: US 2025/0143376 A1
(43) Pub. Date: May 8, 2025

(54) ELECTRONIC ATOMIZATION DEVICE

(71) Applicant: SHENZHEN SMOORE TECHNOLOGY LIMITED, Shenzhen (CN)

(72) Inventors: Longjiang WANG, Shenzhen (CN); Feng XIAO, Shenzhen (CN); Renqing HE, Shenzhen (CN); Dongxu PENG, Shenzhen (CN); Meifan XUAN, Shenzhen (CN)

(21) Appl. No.: 19/012,041

(22) Filed: Jan. 7, 2025

Related U.S. Application Data
(63) Continuation of application No. PCT/CN2022/106102, filed on Jul. 15, 2022.

(51) Int. Cl. A24F 40/465; H03J 1/18; H05B 6/06

(52) U.S. Cl. CPC A24F 40/465; H03J 1/18; H03J 2200/01; H05B 6/06

(57) ABSTRACT

An electronic atomization device includes: a heating element for atomizing an aerosol-forming material: an electromagnetic heating circuit with an inverse class-E characteristic; a power supply circuit connected to the electromagnetic heating circuit so as to supply power to the electromagnetic heating circuit; and a drive circuit connected to the electromagnetic heating circuit so as to generate a drive signal. The electromagnetic heating circuit controls, based on a change of the drive signal, the heating element to atomize the aerosol-forming material.

### CROSS-REFERENCE TO PRIOR APPLICATION

This application is a continuation of International Patent Application No. PCT/CN2022/106102, filed on Jul. 15, 2022. The entire disclosure is hereby incorporated by reference herein.

### FIELD

This application relates to the field of electronic atomization, and in particular, to an electronic atomization device.

### BACKGROUND

In the field of electronic atomization technologies, a heating element in an electronic atomization device needs to release enough power to enable a temperature of an aerosol-forming material in the electronic atomization device to reach a target temperature, thereby meeting a smoking requirement of a user.

Generally, after a voltage is increased by a boost circuit, the increased voltage is inputted into another control circuit, so as to obtain a required power.

However, when an output power is increased by connecting the boost circuit to another control circuit, control complexity of the electronic atomization device is increased, resulting in a high failure rate of the electronic atomization device.

### SUMMARY

In an embodiment, the present invention provides an electronic atomization device, comprising: a heating element configured to atomize an aerosol-forming material: an electromagnetic heating circuit with an inverse class-E characteristic; a power supply circuit connected to the electromagnetic heating circuit and configured to supply power to the electromagnetic heating circuit; and a drive circuit connected to the electromagnetic heating circuit and configured to generate a drive signal, wherein the electromagnetic heating circuit is configured to control, based on a change of the drive signal, the heating element to atomize the aerosol-forming material.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a schematic structural diagram of an electronic atomization device in an embodiment.

FIG. 2 is a schematic diagram of a principle of an electronic atomization device in an embodiment.

FIG. 3 is a schematic diagram of a principle of an electronic atomization device in an embodiment.

FIG. 4 is a schematic diagram of a principle of an electronic atomization device in another embodiment.

FIG. 5 is a schematic diagram of a principle of an electronic atomization device in yet another embodiment.

FIG. 6 is a schematic diagram of a principle of an electronic atomization device in an embodiment.

FIG. 7 is a schematic diagram of a principle of an electronic atomization device in another embodiment.

FIG. 8 is a schematic diagram of a principle of an electronic atomization device in yet another embodiment.

FIG. 9 is a schematic diagram of a principle of an electronic atomization device in yet another embodiment.

FIG. 10 is a schematic diagram of a principle of an electronic atomization device in yet another embodiment.

FIG. 11 is a schematic diagram of a principle of an electronic atomization device in an embodiment.

FIG. 12 is a structural block diagram of an electronic atomization device in an embodiment.

FIG. 13 is a schematic diagram of simulation results in an embodiment.

### DETAILED DESCRIPTION

In an embodiment, the present invention provides an electronic atomization device that can decrease a failure rate of the electronic atomization device.

In an embodiment, the present invention provides an electronic atomization device, including a heating element for atomizing an aerosol-forming material, and further including:
an electromagnetic heating circuit with an inverse class-E characteristic;
a power supply circuit, connected to the electromagnetic heating circuit with an inverse class-E characteristic, and configured to supply power to the electromagnetic heating circuit with an inverse class-E characteristic; and
a drive circuit, connected to the electromagnetic heating circuit with an inverse class-E characteristic, and configured to generate a drive signal.

The electromagnetic heating circuit with an inverse class-E characteristic is configured to control, based on a change of the drive signal, the heating element to atomize the aerosol-forming material.

In one embodiment, the electromagnetic heating circuit with an inverse class-E characteristic includes a switch circuit, a choke inductor L3, an inductance coil L1, a capacitor C1, and a capacitor C7, and the choke inductor L3 is configured to provide a stable direct current (DC) source for the electromagnetic heating circuit with an inverse class-E characteristic, to cause the capacitor C1 and the inductance coil L1 to form a first resonant circuit to provide energy for the heating element when the switch circuit is turned on, and cause the inductance coil L1, the capacitor C1, and the capacitor C7 to jointly form a second resonant circuit to provide energy for the heating element when the switch circuit is turned off.

In one embodiment, the switch circuit is a switch transistor M1.

In one embodiment, a control terminal of the switch transistor M1 is connected to the drive circuit, an input terminal of the switch transistor M1 is connected to a first end of the inductance coil L1, a second end of the inductance coil L1 is connected to the power supply circuit through the choke inductor L3, an output terminal of the switch transistor M1 is grounded, a first end of the capacitor C1 is grounded, and a second end of the capacitor C1 is connected to a common terminal of the choke inductor L3 and the inductance coil L1.

In one embodiment, when the drive signal changes from a low level to a high level, the switch transistor M1 is turned on, the capacitor C7 is short-circuited, the capacitor C1 discharges, and the inductance coil L1 performs charging. If the drive signal changes from the high level to the low level, the switch transistor M1 is turned off, the inductance coil L1 charges the capacitor C7, and after the charging of the capacitor C7 is completed, the inductance coil L1 charges the capacitor C1 to trigger generation of a high-frequency alternating current (AC) signal. The high-frequency AC signal triggers the inductance coil L1 to generate a magnetic field, and the magnetic field causes the heating element to generate heat and atomize the aerosol-forming material.

In one embodiment, the power supply circuit includes a resistor R2 and a resistor R3. A first end of the resistor R2 is grounded, a power supply is connected between a second end of the resistor R2 and a first end of the resistor R3, and a second end of the resistor R3 is connected to the electromagnetic heating circuit with an inverse class-E characteristic.

In one embodiment, the power supply circuit further includes a switch transistor M2. A control terminal of the switch transistor M2 is connected to the second end of the resistor R2, an input terminal of the switch transistor M2 is connected to the power supply, and an output terminal of the switch transistor M2 is connected to the first end of the resistor R3.

In one embodiment, the power supply circuit further includes an energy storage filter circuit. A first end of the energy storage filter circuit is connected between the resistor R3 and the electromagnetic heating circuit with an inverse class-E characteristic, and a second end of the energy storage filter circuit is grounded.

In one embodiment, the energy storage filter circuit includes at least one capacitor.

In one embodiment, the energy storage filter circuit includes a capacitor C2, a capacitor C3, and a capacitor C4. One end of the capacitor C2, the capacitor C3, and the capacitor C4 after being connected in parallel is used as the first end of the energy storage filter circuit, and an other end thereof is used as the second end of the energy storage filter circuit.

In one embodiment, the drive circuit includes a signal source V4, a switch transistor Q1, and a switch transistor Q2. The signal source V4 is connected to a control terminal of the switch transistor Q1 and a control terminal of the switch transistor Q2, an input terminal of the switch transistor Q1 is connected to a driving power supply, an output terminal of the switch transistor Q1 is connected to an input terminal of the switch transistor Q2 and connected to the electromagnetic heating circuit with an inverse class-E characteristic, and an output terminal of the switch transistor Q2 is grounded.

In one embodiment, the drive circuit further includes a resistor R5. The output terminal of the switch transistor Q1 is connected to the electromagnetic heating circuit with an inverse class-E characteristic through the resistor R5. In one embodiment, the drive circuit further includes a resistor R1 and a resistor R4. The signal source V4 is connected to a first end of the resistor R1 and a first end of the resistor R4, a second end of the resistor R1 is connected to the control terminal of the switch transistor Q1, and a second end of the resistor R4 is connected to the control terminal of the switch transistor Q2.

In one embodiment, the drive circuit further includes a capacitor C5. The signal source V4 is connected to the first end of the resistor R1 and the first end of the resistor R4 through the capacitor C5. In one embodiment, the drive circuit further includes a resistor R6. A first end of the resistor R6 is grounded, and a second end of the resistor R6 is connected between the output terminal of the switch transistor Q1 and the input terminal of the switch transistor Q2.

The foregoing electronic atomization device includes a heating element for atomizing an aerosol-forming material, and further includes an electromagnetic heating circuit with an inverse class-E characteristic, a power supply circuit connected to the electromagnetic heating circuit with an inverse class-E characteristic and configured to supply power to the electromagnetic heating circuit with an inverse class-E characteristic, and a drive circuit connected to the electromagnetic heating circuit with an inverse class-E characteristic and configured to generate a drive signal. In this way, the electromagnetic heating circuit with an inverse class-E characteristic may control, based on a change of the drive signal, the heating element to atomize the aerosol-forming material. The control principle is simple, and the failure rate of the electronic atomization device may be reduced.

The embodiments of technical solutions of this application are to be described below in detail with reference to the accompanying drawings. The following embodiments are only used to describe the technical solutions of this application more clearly, and therefore are only used as examples and cannot be used to limit the protection scope of this application.

Unless otherwise defined, meanings of all technical and scientific terms used herein are the same as those usually understood by a person skilled in the art to which this application belongs. The terms used herein are only for the purpose of describing the specific embodiments, and are not intended to limit this application. The terms “include”, “have”, and any variant thereof in the specification, the claims, and the above accompanying drawings of this application are intended to cover a non-exclusive inclusion.

In the description of the embodiments of this application, the technical terms “first”, “second”, and the like are merely used to distinguish between different objects, and should not be understood as indicating or implying relative importance or implying a number, specific order, or primary-secondary relationship of indicated technical features. In the description of the embodiments of this application, “a plurality of” means two or more, unless otherwise explicitly and specifically defined.

The “embodiment” mentioned in this specification means that particular features, structures, or characteristics described with reference to the embodiments may be included in at least one embodiment of this application. The phrase appearing at various locations in this specification does not necessarily refer to a same embodiment, and is not an independent or alternative embodiment mutually exclusive of another embodiment. A person skilled in the art explicitly or implicitly understands that the embodiments described in this specification may be combined with other embodiments.

In the description of the embodiments of this application, a term “and/or” is merely an association relationship describing related objects, which indicates that there may be three relationships, for example, A and/or B may indicate three cases: only A exists, both A and B exist, and only B exists. In addition, the character “/” in this specification generally indicates an “or” relationship between a preceding associated object and a succeeding associated object.

In the description of the embodiments of this application, a term “a plurality of” means two or more (including two). Similarly, “a plurality of groups” means two or more groups (including two groups), and “a plurality of pieces” means two or more pieces (including two pieces).

In the description of the embodiments of this specification, it should be understood that orientation or position relationships indicated by the technical terms such as “center”, “longitudinal”, “transverse”, “length”, “width”, “thickness”, “on”, “below”, “front”, “back”, “left”, “right”, “vertical”, “horizontal”, “top”, “bottom”, “inside”, “outside”, “clockwise”, “anticlockwise”, “axial direction”, “radial direction”, and “circumferential direction” are based on orientation or position relationships shown in the accompanying drawings, and are used only for ease and brevity of description of the embodiments of this specification, rather than indicating or implying that the mentioned apparatus or element needs to have a particular orientation or be constructed and operated in a particular orientation. Therefore, such terms should not be construed as a limitation on the embodiments of this specification.

In the description of the embodiments of this specification, unless otherwise explicitly specified or defined, the technical terms such as “mount”, “connect”, “connection”, and “fix” should be understood in a broad sense. For example, the connection may be a fixed connection, a detachable connection, or an integral connection, the connection may be a mechanical connection or an electrical connection; or the connection may be a direct connection, an indirect connection through an intermediate medium, internal communication between two elements, or an interaction relationship between two elements. A person of ordinary skill in the art can understand specific meanings of the foregoing terms in the embodiments of this application according to a specific situation.

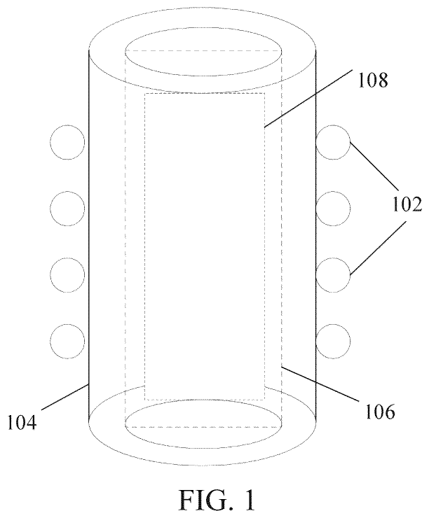

As shown in FIG. 1, a schematic structural diagram of an electronic atomization device is provided. The electronic atomization device includes an inductance coil 102, a coil support 104, and a metal induction heating element 108 arranged in an aerosol-forming material 106. Specifically, the electronic atomization device may cause, based on the inductance coil, the heating element to generate heat and atomize the aerosol-forming material, so as to meet a smoking requirement of a user.

The inductance coil 102 may be a coil made of for example a flat wire, a round wire, or an electromagnetic wire, and the coil support 104 may be slotted or unslotted. The aerosol-forming material 106 may be in the form of liquid, gel, paste, solid, or the like, which may be specifically set based on an actual application scenario. For example, when the aerosol-forming material is a solid, the solid may be in the form of fragments, granules, powder, strips, or sheets.

On the basis of the schematic diagram shown in FIG. 1, in one embodiment, the electronic atomization device includes a power supply circuit, a drive circuit, an electromagnetic heating circuit with an inverse class-E characteristic, and a heating element for atomizing an aerosol-forming material. The power supply circuit is connected to the electromagnetic heating circuit with an inverse class-E characteristic, and configured to supply power to the electromagnetic heating circuit with an inverse class-E characteristic. The drive circuit is connected to the electromagnetic heating circuit with an inverse class-E characteristic, and configured to generate a drive signal. The electromagnetic heating circuit with an inverse class-E characteristic is configured to control, based on a change of the drive signal, the heating element to atomize the aerosol-forming material.

The electromagnetic heating circuit with an inverse class-E characteristic has a cavity formed therein. The heating element may be arranged in the cavity. In this way, the electromagnetic heating circuit with an inverse class-E characteristic may provide energy for the heating element based on the change of the drive signal, so that the heating element may atomize the aerosol-forming material after generating heat.

It may be understood that a specific positional relationship between the electromagnetic heating circuit with an inverse class-E characteristic and the heating element may also be set based on an actual application scenario, which is not specifically limited in this embodiment.

In order to better describe the implementation principle of the electronic atomization device controlling the heating element to generate heat, in one embodiment, the electromagnetic heating circuit with an inverse class-E characteristic includes a switch circuit, a choke inductor L3, an inductance coil L1, a capacitor C1, and a capacitor C7. The choke inductor L3 is configured to provide a stable direct current (DC) source for the electromagnetic heating circuit with an inverse class-E characteristic, so that the capacitor C1 and the inductance coil L1 may form a first resonant circuit to provide energy for the heating element when the switch circuit is turned on, and the inductance coil L1, the capacitor C1, and the capacitor C7 may jointly form a second resonant circuit to provide energy for the heating element when the switch circuit is turned off. In addition, the capacitor C7 may be further configured to protect the switch circuit when the switch circuit is turned off.

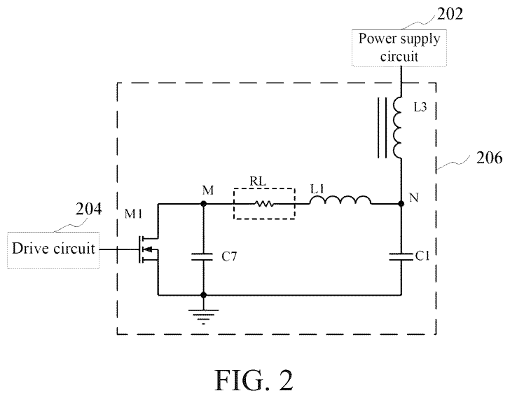

In one embodiment, the switch circuit may be a switch transistor M1. Specifically, as shown in FIG. 2, a schematic structural diagram of an electronic atomization device is provided. A control terminal of the switch transistor M1 is connected to the drive circuit, an input terminal of the switch transistor M1 is connected to a first end of the inductance coil L1, a second end of the inductance coil L1 is connected to the power supply circuit through the choke inductor L3, an output terminal of the switch transistor M1 is grounded, a first end of the capacitor C1 is grounded, a second end of the capacitor C1 is connected to a common terminal of the choke inductor L3 and the inductance coil L1, a first end of the capacitor C7 is grounded, and a second end of the capacitor C7 is connected to the input terminal of the switch transistor M1.

As shown in FIG. 2, RL is a coupling impedance portion of the heating element in a circuit, and the heating element is located in the inductance coil L1. On a printed circuit board, the inductance coil L1 is directly connected to a point M where the switch transistor M1 and the capacitor C7 are connected, and the capacitor C7 may be configured to protect the switch transistor M1, so that a voltage at the point M may be 0 at a moment the switch transistor M1 is closed. The switch transistor M1 may be a field-effect transistor or a triode. If the switch transistor M1 is a field-effect transistor, the control terminal of the switch transistor M1 is a gate of the field-effect transistor, the input terminal of the switch transistor M1 is a drain of the field-effect transistor, and the output terminal of the switch transistor M1 is a source of the field-effect transistor.

Specifically, as shown in FIG. 2, the power supply circuit may supply power to the electromagnetic heating circuit with an inverse class-E characteristic. After the drive circuit generates a drive signal, the electromagnetic heating circuit with an inverse class-E characteristic may control, based on a change of the drive signal, the heating element to atomize the aerosol-forming material. Compared with a manner of connecting a boost circuit to another control circuit to increase an output power, the electromagnetic heating circuit with an inverse class-E characteristic may control, based on the change of the drive signal, the heating element to atomize the aerosol-forming material. The control principle is simple, so that a failure rate of the electronic atomization device may be reduced. The electronic atomization device may further include a controller. The drive circuit may be triggered by the controller to generate a drive signal. The controller may be a micro controller unit (MCU), other types of chips for controlling a process, or the like, which is not limited in this embodiment.

Specifically, in an initial state, when the drive signal changes from a low level to a high level, the switch transistor M1 is turned on, the capacitor C7 is short-circuited, and the capacitor C1 discharges. In this case, the voltage at the point M is close to zero, a circuit current flows through the inductance coil L1, and the inductance coil L1 performs charging. When the drive signal changes from the high level to the low level, the switch transistor M1 is turned off, a direction of the current flowing through the inductance coil L1 remains unchanged, and the inductance coil L1 charges the capacitor C7. In this case, a potential at the point M is pulled up, and after the charging of the capacitor C7 is completed, the potential at the point M is higher than a point potential. The point potential is a potential of an ungrounded terminal of the capacitor C2. The inductance coil L1 charges the capacitor C1. In this case, the potential at the point M drops to trigger generation of a high-frequency AC signal. The high-frequency AC signal triggers the inductance coil L1 to generate a magnetic field, and the magnetic field causes the heating element to generate heat and atomize the aerosol-forming material.

The drive signal may be a signal obtained based on a pulse width modulation (PWM) technology. In a normal operating process, an operating state of the electromagnetic heating circuit with an inverse class-E characteristic may be divided into the following four states.
State 1: From a time at which the drive signal changes from a low level to a high level until the end of a first half of a period of time in which the drive signal is at the high level, C1 is charged, and the L1 discharges.
State 2: Until the end of a second half of a period of time in which the drive signal is at the high level, the C1 discharges, and the L1 performs charging.
State 3: From a time at which the drive signal changes from the high level to the low level until the end of a first half of a period of time in which the drive signal is at the low level, the C1 discharges, and the L1 performs charging.
State 4: Until the end of a second half of a period of time in which the drive signal is at the low level, the C1 is charged, and the L1 discharges.

Moreover, when a next drive signal at the high level arrives, the switch transistor M1 is turned on, and the capacitor C7 has just finished discharging. In this case, the potential at the point M just drops to zero. Through alternation of the high level and the low level based on the drive signal, the electromagnetic heating circuit with an inverse class-E characteristic may continuously generate the high-frequency AC signal, and then the heating element continuously generate heat to atomize the aerosol-forming material.

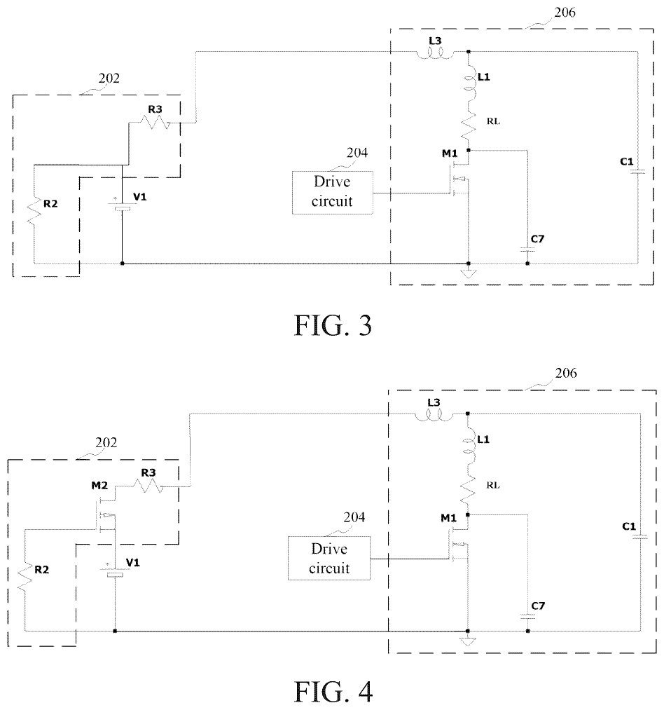

On the basis of the schematic diagram shown in FIG. 2, in one embodiment, as shown in FIG. 3, a schematic diagram of a principle of an electronic atomization device is provided. A power supply circuit 202 includes a resistor R2 and a resistor R3. A first end of the resistor R2 is grounded, a power supply V1 is connected between a second end of the resistor R2 and a first end of the resistor R3, and a second end of the resistor R3 is connected to the electromagnetic heating circuit with an inverse class-E characteristic. Specifically, the second end of the resistor R3 is connected to a choke inductor L3.

On the basis of the schematic diagram shown in FIG. 3, in one embodiment, as shown in FIG. 4, the power supply circuit 202 further includes a switch transistor M2. A control terminal of the switch transistor M2 is connected to the second end of the resistor R2, an input terminal of the switch transistor M2 is connected to the power supply V1, and an output terminal of the switch transistor M2 is connected to the first end of the resistor R3. In this way, low power consumption of the power supply circuit in a standby state may be better realized through the switch transistor M2.

A positive terminal of the power supply V1 is connected to the input terminal of the switch transistor M2, and a negative terminal of the power supply V1 is grounded. The switch transistor M2 may be a field-effect transistor or a triode. In this embodiment, the switch transistor M2 is the field-effect transistor, the control terminal of the switch transistor M2 is a gate of the field-effect transistor, the input terminal of the switch transistor M2 is a source of the field-effect transistor, and the output terminal of the switch transistor M2 is a drain of the field-effect transistor.

It may be understood that the switch transistor M2 may further be connected to the controller. In this way, the controller may control on/off of the switch transistor M2, so that the switch transistor M2 may supply power to the electromagnetic heating circuit with an inverse class-E characteristic.

On the basis of the schematic diagram shown in FIG. 4, in one embodiment, the power supply circuit may further include an energy storage filter circuit 2021. A first end of the energy storage filter circuit 2021 is connected between the resistor R3 and the electromagnetic heating circuit with an inverse class-E characteristic. Specifically, the first end of the energy storage filter circuit 2021 is connected between the resistor R3 and the choke inductor L3, and a second end of the filter assembly is grounded.

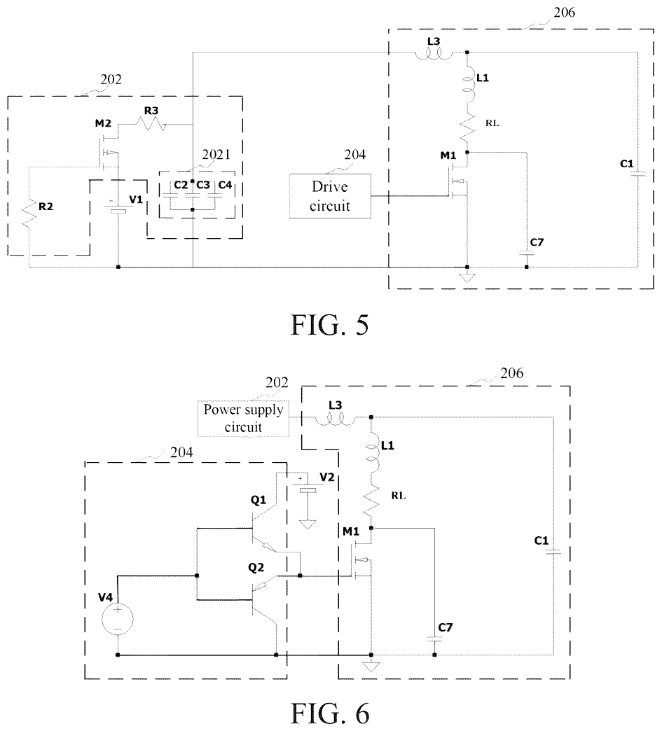

In one embodiment, the energy storage filter circuit includes at least one capacitor. Specifically, as shown in FIG. 5, the energy storage filter circuit 2021 may include a capacitor C2, a capacitor C3, and a capacitor C4. One end of the capacitor C2, the capacitor C3, and the capacitor C4 connected in parallel is used as the first end of the energy storage filter circuit 2021, and the other end is used as the second end of the energy storage filter circuit 2021. In this way, a better filtering effect can be achieved, to realize a higher filtering frequency.

On the basis of the schematic diagram shown in FIG. 2, in one embodiment, as shown in FIG. 6, a schematic diagram of a principle of an electronic atomization device is provided. A drive circuit 204 includes a signal source V4, a switch transistor Q1, and a switch transistor Q2. The signal source V4 is connected to a control terminal of the switch transistor Q1 and a control terminal of the switch transistor Q2, an input terminal of the switch transistor Q1 is connected to a driving power supply V2, an output terminal of the switch transistor Q1 is connected to an input terminal of the switch transistor Q2 and connected to the electromagnetic heating circuit with an inverse class-E characteristic, and an output terminal of the switch transistor Q2 is grounded.

The output terminal of the switch transistor Q1 is connected to the electromagnetic heating circuit with an inverse class-E characteristic. Specifically, the output terminal of the switch transistor Q1 is connected to the control terminal of the switch transistor M1. The driving power supply V2 supplies power to the drive circuit. One end of the driving power supply V2 is connected to the input terminal of the switch transistor Q1, and the other end of the driving power supply V2 is grounded. The signal source V4 is configured to provide a drive signal. One end of the signal source V4 is grounded, and the other end of the signal source V4 is connected to the control terminal of the switch transistor Q1 and the control terminal of the switch transistor Q2.

The switch transistor Q1 and the switch transistor Q2 may be triodes or field-effect transistors. In this embodiment, the switch transistor Q1 and the switch transistor Q2 are both triodes. The control terminal of the switch transistor Q1 is a base of the triode, the input terminal of the switch transistor Q1 is a collector of the triode, and the output terminal of the switch transistor Q1 is an emitter of the triode. The control terminal of the switch transistor Q2 is the base of the triode, the input terminal of the switch transistor Q2 is the emitter of the triode, and the output terminal of the switch transistor Q2 is the collector of the triode.

It may be understood that in a specific circuit implementation, the functions implemented by the foregoing drive circuit may also be implemented by using a dedicated driver chip, which is not limited in this embodiment.

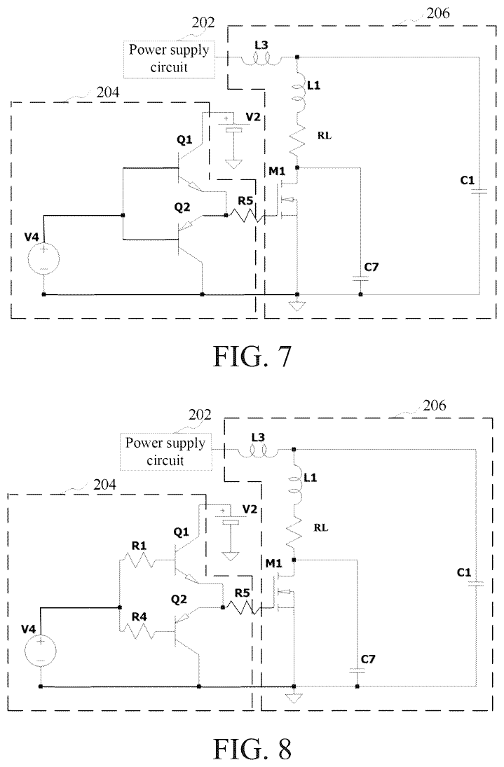

On the basis of the schematic diagram shown in FIG. 6, in one embodiment, as shown in FIG. 7, a schematic diagram of a principle of an electronic atomization device is provided. The drive circuit 204 may further include a resistor R5. The output terminal of the switch transistor Q1 is connected to the electromagnetic heating circuit with an inverse class-E characteristic through the resistor R5. Specifically, the output terminal of the switch transistor Q1 is connected to the control terminal of the switch transistor M1 through the resistor R5. In this way, breakdown of surrounding components and devices as a result of an excessively high switching rate of the switch transistor M1 may be avoided.

On the basis of the schematic diagram shown in FIG. 7, as shown in FIG. 8, the drive circuit 204 may further include a resistor R1 and a resistor R4. The signal source V4 is connected to a first end of the resistor R1 and a first end of the resistor R4. A second end of the resistor R1 is connected to the control terminal of the switch transistor Q1, and a second end of the resistor R4 is connected to the control terminal of the switch transistor Q2. In this way, the resistor R1 and the resistor R4 may play a current-limiting role, and prevent the switch transistor Q1 and the switch transistor Q2 from being burnt out due to an excessive current.

It may be understood that the signal source V4 may further be connected to the controller. In this way, the controller may trigger the signal source V4 to generate a drive signal, so that the electromagnetic heating circuit with an inverse class-E characteristic may control, based on a change of the drive signal, the heating element to atomize the aerosol-forming material.

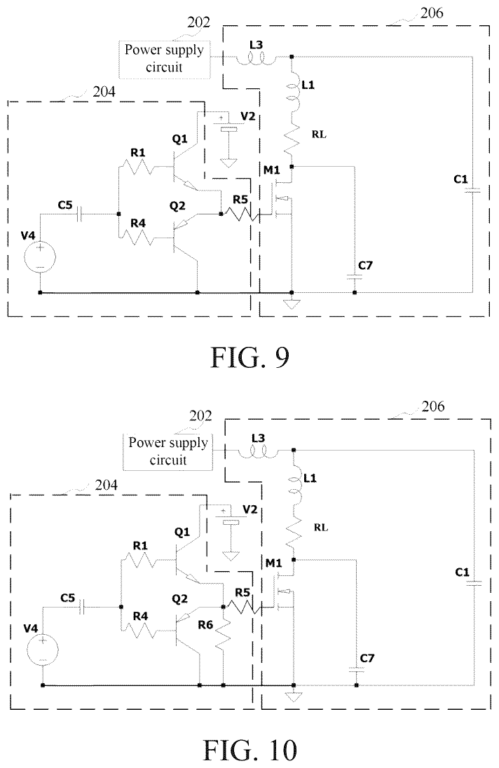

It may be understood that the drive signal may further be generated by an internal circuit of the controller or by a separate signal source, which may be specifically set based on an actual application scenario, and is not specifically limited in this embodiment. On the basis of the schematic diagram shown in FIG. 8, as shown in FIG. 9, the drive circuit 204 may further include a capacitor C5. The signal source V4 is connected to the first end of the resistor R1 and the first end of the resistor R4 through the capacitor C5. In this way, high-frequency interference may be filtered out, thereby improving stability of the drive circuit.

On the basis of the schematic diagram shown in FIG. 9, as shown in FIG. 10, the drive circuit 204 may further include a resistor R6. A first end of the resistor R6 is grounded, and a second end of the resistor R6 is connected between the output terminal of the switch transistor Q1 and the input terminal of the switch transistor Q2. In this way, the resistor R6 may prevent damage to the switch transistor Q2 as a result of an excessive current in the drive circuit.

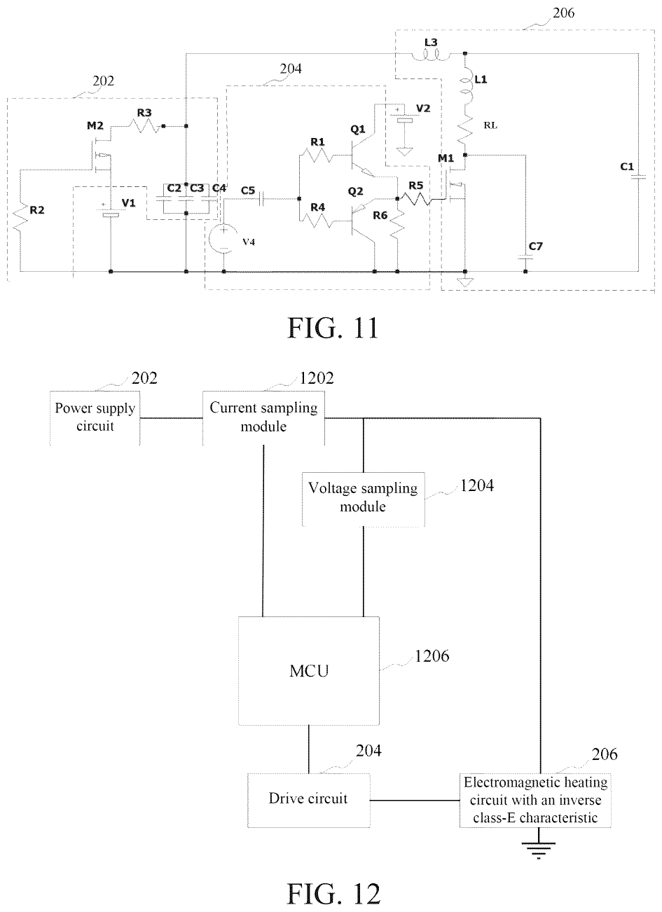

Based on the above content, in one embodiment, as shown in FIG. 11, a schematic diagram of a circuit principle of an electronic atomization device is provided. The electronic atomization device includes an electromagnetic heating circuit 206 with an inverse class-E characteristic, a power supply circuit 202, and a drive circuit 204. For specific content of the electromagnetic heating circuit 206 with an inverse class-E characteristic, the power supply circuit 202, and the drive circuit 204, reference may be made to the foregoing content description, and details are not described herein again.

Based on the above content, in one embodiment, as shown in FIG. 12, a structural block diagram of an electronic atomization device is provided. The electronic atomization device may include a current sampling module 1202, a voltage sampling module 1204, an MCU 1206, an electromagnetic heating circuit 206 with an inverse class-E characteristic, a power supply circuit 202, and a drive circuit 204. The power supply circuit 202 is configured to supply power to the current sampling module 1202, the voltage sampling module 1204, and the electromagnetic heating circuit 206 with an inverse class-E characteristic.

Specifically, the current sampling module may obtain a current signal from the electromagnetic heating circuit with an inverse class-E characteristic, and the voltage sampling module may obtain a voltage signal from the electromagnetic heating circuit with an inverse class-E characteristic. The MCU may determine an output power of the electromagnetic heating circuit with an inverse class-E characteristic based on the voltage signal and the current signal. Based on the power, the MCU may trigger the drive circuit to generate a drive signal, and the electromagnetic heating circuit with an inverse class-E characteristic may adjust the output power based on a change of the triggered drive signal.

In an embodiment, if a capacitance value of the capacitor C7, a capacitance value of the capacitor C1, an inductance value of the inductance coil L1, and an impedance value of the RL in the electromagnetic heating circuit with an inverse class-E characteristic are all fixed, the output power of the electromagnetic heating circuit with an inverse class-E characteristic may be adjusted by adjusting a driving frequency of the drive signal. For example, if the driving frequency of the drive signal is closer to an oscillation frequency of the electromagnetic heating circuit with an inverse class-E characteristic, the output power of the electromagnetic heating circuit with an inverse class-E characteristic may be increased. If the driving frequency of the drive signal is farther away from the oscillation frequency of the electromagnetic heating circuit with an inverse class-E characteristic, the output power of the electromagnetic heating circuit with an inverse class-E characteristic may be reduced, which may be specifically set based on an actual application scenario, and is not limited in this embodiment.

In another embodiment, if the driving frequency of the drive signal is fixed, the output power of the electromagnetic heating circuit with an inverse class-E characteristic may be adjusted by adjusting the capacitance value of the capacitor C1, the inductance value of the inductance coil L1, the impedance value of the RL, and the capacitance value of the capacitor C7.

The capacitance value of the capacitor C1 satisfies the following formula: C1=(π⁴+16)/(2π(π²+4))×Pₒ/(ωVcc²), the impedance value of the RL satisfies the following formula: RL˜1.7337×Vcc²/Pₒ, and the inductance value of the inductance coil L1 satisfies the following formula: L1˜Vcc²/(Pₒ×πω), where Vcc is an input power supply, that is, an output voltage of the power supply V1, Pₒ is a power that needs to be outputted by the electromagnetic heating circuit with an inverse class-E characteristic, and ω is the oscillation frequency of the electromagnetic heating circuit with an inverse class-E characteristic.

The capacitance value of the capacitor C7 needs to be adjusted based on an output parameter of the switch transistor (for example, an input capacitance, an output capacitance, or a capacitance effect of the switch transistor) and an impedance parameter of the PCB. Moreover, the capacitance value of the capacitor C7 further needs to be deduced through an ideal state, and then is adjusted based on high-frequency parameter changes (for example, a capacitive reactance characteristic change and an internal resistance change of the inductance coil L1, and a stray inductance change and a capacitance change of the PCB) of a component.

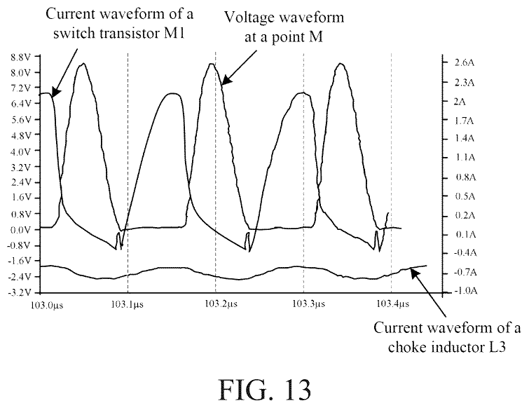

In order to verify feasibility of a circuit design in the electronic atomization device, a simulation circuit may be designed based on the schematic diagram shown in FIG. 11. As shown in FIG. 13, a schematic diagram of simulation results is provided. It may be seen that a voltage waveform at a point M does not overlap with a current waveform of the switch transistor M1 and a current waveform of the choke inductor L3.

Before the power is adjusted based on the electromagnetic heating circuit with an inverse class-E characteristic, an input power pin may be obtained based on a measured voltage between the choke inductor L3 and the inductance coil L1 and a current outputted by the power supply voltage V1. After the power is adjusted based on the electromagnetic heating circuit with an inverse class-E characteristic, an output power pout may be obtained based on the measured voltage at the first end of the choke inductor L3 and the current flowing through the RL. Therefore, a circuit power pout/pin of about 96% may be obtained.

Therefore, the simulation circuit designed based on the schematic diagram shown in FIG. 11 may have a circuit efficiency of over 90%. A specific value of the circuit efficiency may be set based on an actual application scenario.

It should be noted that in ideal conditions, a conventional class-E amplifier Vd˜3.5620Vdc, and a peak voltage of an inverse class-E power amplifier Vd˜2.8621Vdc. The peak voltage of the inverse class-E power amplifier is lower by about 20% than the peak voltage of the conventional class-E amplifier. Therefore, a requirement for a withstand voltage of a switch transistor may be lowered, and a parasitic inductance of a drain of the switch transistor (for example, the RL in FIG. 2) may be used as a part of the oscillation inductance L1, which is less than the inductance required by the conventional class-E amplifier.

Based on the above content, the electronic atomization device provided in this application has fewer circuit devices, a lower failure rate, and simpler control, and non-overlapping of the voltage waveform and the current waveform may be realized by adjusting circuit parameters. Only a device impedance loss exists in the circuit, which greatly improves the circuit efficiency and increases an atomization speed, so as to improve a smoking effect of the user.

The technical features of the foregoing embodiments may be randomly combined. To make the description concise, not all possible combinations of the technical features in the foregoing embodiments are described. However, the combinations of these technical features are considered as falling within the scope recorded in this specification provided that no conflict exists.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. An electronic atomization device, comprising:
a heating element configured to atomize an aerosol-forming material:
an electromagnetic heating circuit with an inverse class-E characteristic;
a power supply circuit connected to the electromagnetic heating circuit and configured to supply power to the electromagnetic heating circuit; and
a drive circuit connected to the electromagnetic heating circuit and configured to generate a drive signal,
wherein the electromagnetic heating circuit is configured to control, based on a change of the drive signal, the heating element to atomize the aerosol-forming material.

2. The electronic atomization device of claim 1, wherein the electromagnetic heating circuit comprises a switch circuit, a choke inductor L3, an inductance coil L1, a capacitor C1, and a capacitor C7, and
wherein the choke inductor L3 is configured to provide a stable direct current (DC) source for the electromagnetic heating circuit so as to cause the capacitor C1 and the inductance coil L1 to form a first resonant circuit to provide energy for the heating element when the switch circuit is turned on, and so as to cause the inductance coil L1, the capacitor C1, and the capacitor C7 to jointly form a second resonant circuit to provide energy for the heating element when the switch circuit is turned off.

3. The electronic atomization device of claim 2, wherein the switch circuit comprises a switch transistor M1.

4. The electronic atomization device of claim 3, wherein a control terminal of the switch transistor M1 is connected to the drive circuit,
wherein an input terminal of the switch transistor M1 is connected to a first end of the inductance coil L1,
wherein a second end of the inductance coil L1 is connected to the power supply circuit through the choke inductor L3,
wherein an output terminal of the switch transistor M1 is grounded,
wherein a first end of the capacitor C1 is grounded,
wherein a second end of the capacitor C1 is connected to a common terminal of the choke inductor L3 and the inductance coil L1,
wherein a first end of the capacitor C7 is grounded, and
wherein a second end of the capacitor C7 is connected to the input terminal of the switch transistor M1.

5. The electronic atomization device of claim 2, wherein, when the drive signal changes from a low level to a high level, the switch transistor M1 is turned on, the capacitor C7 is short-circuited, the capacitor C1 discharges, and the inductance coil L1 performs charging,
wherein, when the drive signal changes from the high level to the low level, the switch transistor M1 is turned off, the inductance coil L1 charges the capacitor C7, and after the charging of the capacitor C7 is completed, the inductance coil L1 charges the capacitor C1 to trigger generation of a high-frequency alternating current (AC) signal, and
wherein the high-frequency AC signal triggers the inductance coil L1 to generate a magnetic field that causes the heating element to generate heat and atomize the aerosol-forming material.

6. The electronic atomization device of claim 1, wherein the power supply circuit comprises a resistor R2 and a resistor R3, and
wherein a first end of the resistor R2 is grounded, a power supply is connected between a second end of the resistor R2 and a first end of the resistor R3, and a second end of the resistor R3 is connected to the electromagnetic heating circuit.

7. The electronic atomization device of claim 6, wherein the power supply circuit further comprises:
a switch transistor M2,
wherein a control terminal of the switch transistor M2 is connected to the second end of the resistor R2,
wherein an input terminal of the switch transistor M2 is connected to the power supply, and
wherein an output terminal of the switch transistor M2 is connected to the first end of the resistor R3.

8. The electronic atomization device of claim 7, wherein the power supply circuit further comprises:
an energy storage filter circuit,
wherein a first end of the energy storage filter circuit is connected between the resistor R3 and the electromagnetic heating circuit, and
wherein a second end of the energy storage filter circuit is grounded.

9. The electronic atomization device of claim 8, wherein the energy storage filter circuit comprises at least one capacitor.

10. The electronic atomization device of claim 9, wherein the energy storage filter circuit comprises a capacitor C2, a capacitor C3, and a capacitor C4,
wherein one end of the capacitor C2, the capacitor C3, and the capacitor C4, after being connected in parallel, is used as the first end of the energy storage filter circuit, and
wherein an other end of the capacitor C2, the capacitor C3, and the capacitor C4, after being connected in parallel, is used as the second end of the energy storage filter circuit.

11. The electronic atomization device of claim 1, wherein the drive circuit comprises a signal source V4, a switch transistor Q1, and a switch transistor Q2,
wherein the signal source V4 is connected to a control terminal of the switch transistor Q1 and a control terminal of the switch transistor Q2,
wherein an input terminal of the switch transistor Q1 is connected to a driving power supply,
wherein an output terminal of the switch transistor Q1 is connected to an input terminal of the switch transistor Q2 and connected to the electromagnetic heating circuit, and
wherein an output terminal of the switch transistor Q2 is grounded.

12. The electronic atomization device of claim 11, wherein the drive circuit further comprises:
a resistor R5, and
wherein the output terminal of the switch transistor Q1 is connected to the electromagnetic heating circuit through the resistor R5.

13. The electronic atomization device of claim 12, wherein the drive circuit further comprises:
a resistor R1 and a resistor R4, and
wherein the signal source V4 is connected to a first end of the resistor R1 and a first end of the resistor R4,
wherein a second end of the resistor R1 is connected to the control terminal of the switch transistor Q1, and
wherein a second end of the resistor R4 is connected to the control terminal of the switch transistor Q2.

14. The electronic atomization device of claim 13, wherein the drive circuit further comprises:
a capacitor C5, and
wherein the signal source V4 is connected to the first end of the resistor R1 and the first end of the resistor R4 through the capacitor C5.

15. The electronic atomization device of claim 14, wherein the drive circuit further comprises:
a resistor R6,
wherein a first end of the resistor R6 is grounded, and
wherein a second end of the resistor R6 is connected between the output terminal of the switch transistor Q1 and the input terminal of the switch transistor Q2.
